(19) United States
(12) Patent Application Publication
(10) Pub. No.: US 2026/0269799 A1
(43) Pub. Date: Sep. 10, 2026

(54) SIGNAL TRANSMISSION CIRCUIT FOR HIGH FREQUENCY TRANSMISSION

(71) Applicant: ASMedia Technology Inc., New Taipei City (TW)

(72) Inventor: Chieh-Jui Ho, New Taipei City (TW)

(73) Assignee: ASMedia Technology Inc., New Taipei City (TW)

(21) Appl. No.: 19/079,482

(22) Filed: Mar. 14, 2025

(30) Foreign Application Priority Data
Mar. 5, 2025 (TW) 114108203

(51) Int. Cl. H03G 5/16; H03K 17/56; H04B 1/04

(52) U.S. Cl. CPC H03G 5/165; H03K 17/56; H04B 1/04; H03G 2201/103

(57) ABSTRACT

A signal transmission circuit for high frequency transmission is provided. The signal transmission circuit includes an equalizer, a resonator, and an adder. The equalizer receives an input signal and gains the input signal to generate a gain signal. The resonator receives the input signal and performs a high-frequency resonance operation on the input signal to generate a high-frequency resonance signal. The adder receives the gain signal and the high-frequency resonance signal, and sums the gain signal and the high-frequency resonance signal to generate an output signal.

### CROSS-REFERENCE TO RELATED APPLICATION

This application claims the priority benefit of Taiwan application serial no. 114108203, filed on Mar. 5, 2025. The entirety of the above-mentioned patent application is hereby incorporated by reference herein and made a part of this specification.

### BACKGROUND

### Technical Field

The disclosure relates to a signal transmission circuit, and in particular relates to a signal transmission circuit for high frequency transmission.

### Description of Related Art

A signal transmission circuit may be used for wired communication transmission. However, when used for high-frequency transmission, the signal transmission circuit itself incurs high-frequency losses. Therefore, how to provide a signal transmission circuit capable of compensating high-frequency signals is one of the research focuses of those skilled in the art.

### SUMMARY

A signal transmission circuit for high-frequency transmission, which may compensate for high-frequency signals, is provided in the disclosure.

In one embodiment of the disclosure, the signal transmission circuit includes an equalizer, a resonator, and an adder. The equalizer receives an input signal and gains the input signal to generate a gain signal. The resonator receives the input signal and performs a high-frequency resonance operation on the input signal to generate a high-frequency resonance signal. The adder is coupled to the equalizer and the resonator. The adder receives the gain signal and the high-frequency resonance signal, and sums the gain signal and the high-frequency resonance signal to generate an output signal.

Based on the above, the resonator performs a high-frequency resonance operation on the input signal to generate a high-frequency resonance signal. The adder compensates the gain signal with the high-frequency resonance signal to generate an output signal. In this way, the high frequency portion of the output signal may be compensated.

### BRIEF DESCRIPTION OF THE DRAWINGS

FIG. 1 is a schematic diagram of a signal transmission circuit according to an embodiment of the disclosure.

FIG. 2 is a schematic diagram of a signal transmission circuit according to an embodiment of the disclosure.

FIG. 3 is a schematic diagram of a signal transmission circuit according to an embodiment of the disclosure.

FIG. 4 is a schematic diagram of a signal transmission circuit according to an embodiment of the disclosure.

FIG. 5 is a schematic diagram of a signal transmission circuit according to an embodiment of the disclosure.

FIG. 6 is a diagram of a damping response of a resonator according to an embodiment of the disclosure.

FIG. 7 is a schematic diagram of a signal transmission circuit according to an embodiment of the disclosure.

FIG. 8 is a schematic diagram of a resonator according to an embodiment of the disclosure.

FIG. 9 is a schematic diagram of an amplifier according to an embodiment of the disclosure.

### DETAILED DESCRIPTION OF DISCLOSED EMBODIMENTS

A portion of the embodiments of the disclosure will be described in detail with reference to the accompanying drawings. Element symbol referenced in the following description will be regarded as the same or similar element when the same element symbol appears in different drawings. These examples are only a portion of the disclosure and do not disclose all possible embodiments of the disclosure. More precisely, these embodiments are only examples within the scope of the patent application of the disclosure.

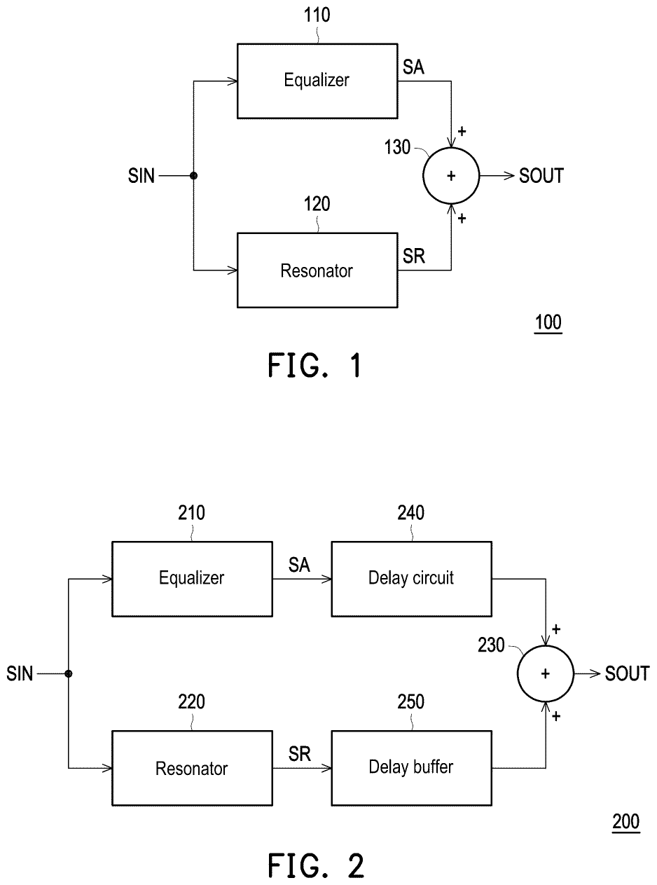

Referring to FIG. 1, FIG. 1 is a schematic diagram of a signal transmission circuit according to an embodiment of the disclosure. In this embodiment, the signal transmission circuit 100 includes an equalizer 110, a resonator 120, and an adder 130. The equalizer 110 receives an input signal SIN and gains the input signal SIN to generate a gain signal SA. The resonator 120 receives an input signal SIN and performs a high-frequency resonance operation on the input signal SIN to generate a high-frequency resonance signal SR. The adder 130 is coupled to the equalizer 110 and the resonator 120. The adder 130 receives the gain signal SA and the high-frequency resonance signal SR. The adder 130 sums the gain signal SA and the high-frequency resonance signal SR to generate an output signal SOUT.

It is worth mentioning that the resonator 120 performs a high-frequency resonance operation on the input signal SIN to generate a high-frequency resonance signal SR. The adder 130 compensates the gain signal SA with the high-frequency resonance signal SR to generate an output signal SOUT. In this way, the high frequency portion of the output signal SOUT may be compensated by the high-frequency resonance signal SR.

Referring to FIG. 2, FIG. 2 is a schematic diagram of a signal transmission circuit according to an embodiment of the disclosure. In this embodiment, the signal transmission circuit 200 includes an equalizer 210, a resonator 220, an adder 230, a delay circuit 240, and a delay buffer 250. The equalizer 210 receives an input signal SIN and gains the input signal SIN to generate a gain signal SA. The delay circuit 240 is coupled between the equalizer 210 and the adder 230. The delay circuit 240 delays the timing of the gain signal SA. The resonator 220 receives an input signal SIN and performs a high-frequency resonance operation on the input signal SIN to generate a high-frequency resonance signal SR. The delay buffer 250 is coupled between the resonator 220 and the adder 230. The delay buffer 250 delays the timing of the high-frequency resonance signal SR.

In this embodiment, the equalizer 210 and the delay circuit 240 may be regarded as a first signal path of the signal transmission circuit 200. In addition, the resonator 220 and the delay buffer 250 may be regarded as a second signal path of the signal transmission circuit 200.

Generally speaking, the high-frequency resonance signal SR has a timing delay compared to the input signal SIN. Therefore, the delay circuit 240 and the delay buffer 250 are designed to match the timing of the high-frequency resonance signal SR and the timing of the gain signal SA.

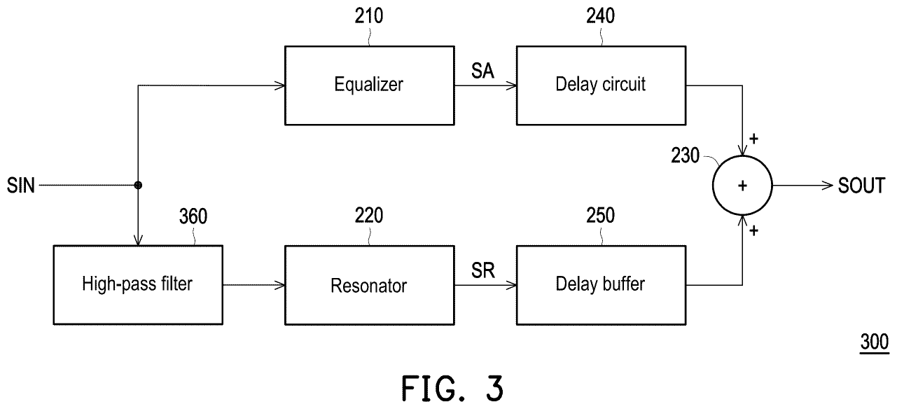

Referring to FIG. 3, FIG. 3 is a schematic diagram of a signal transmission circuit according to an embodiment of the disclosure. In this embodiment, the signal transmission circuit 300 includes an equalizer 210, a resonator 220, an adder 230, a delay circuit 240, a delay buffer 250, and a high-pass filter 360. In this embodiment, the coordinated operations of the equalizer 210, the resonator 220, the adder 230, the delay circuit 240, and the delay buffer 250 have been clearly described in the embodiment of FIG. 2, and thus are not repeated herein.

In this embodiment, the high-pass filter 360 is coupled to the resonator 220. The high-pass filter 360 receives the input signal SIN and filters out the low frequency component of the input signal SIN. The high-pass filter 360 may output the high frequency component of the input signal SIN. Therefore, the resonator 220 performs a high-frequency resonance operation on the high-frequency component of the input signal SIN to generate a high-frequency resonance signal SR.

In this embodiment, the equalizer 210 and the delay circuit 240 may be regarded as a first signal path of the signal transmission circuit 300. Furthermore, the resonator 220, the delay buffer 250, and the high-pass filter 360 may be regarded as a second signal path of the signal transmission circuit 300.

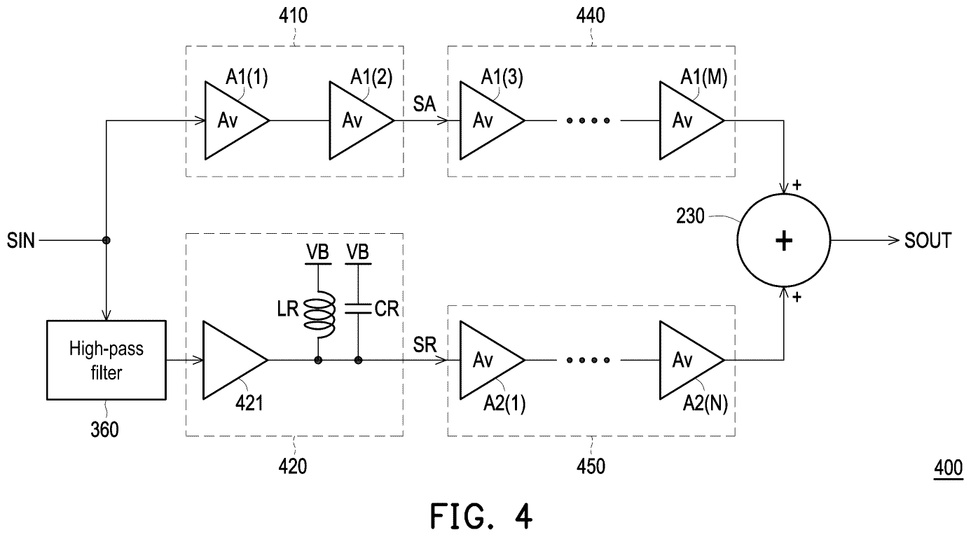

Referring to FIG. 4, FIG. 4 is a schematic diagram of a signal transmission circuit according to an embodiment of the disclosure. In this embodiment, the signal transmission circuit 400 includes an equalizer 410, a resonator 420, an adder 230, a delay circuit 440, a delay buffer 450, and a high-pass filter 360. The equalizer 410 may be implemented by amplifiers A1(1) and A1(2). The delay circuit 440 may be implemented by amplifiers A1(3) to A1(M). The delay buffer 450 may be implemented by amplifiers A2(1) to A2(N). In this embodiment, the amplifiers A1(1) to A1(M) are connected in series. The amplifiers A2(1) to A2(N) are connected in series with each other.

When the resonator 420 generates the high-frequency resonance signal SR, the high-frequency resonance signal SR is delayed in timing compared to the input signal SIN. Therefore, the signal transmission circuit 400 performs a first delay on the timing of the gain signal SA using the amplifiers A1(1) to A1(M), and performs a second delay on the timing of the high-frequency resonance signal SR using the amplifiers A2(1) to A2(N), thereby matching the timing of the high-frequency resonance signal SR and the timing of the gain signal SA. The first delay is greater than the second delay. The number of amplifiers A1(1) to A1(M) connected in series is greater than the number of amplifiers A2(1) to A2(N) connected in series. Assuming that the amplifiers A1(1) to A1(M) and A2(1) to A2(N) have the same delay, (M) is designed to be greater than (N) or greater than (N+1). In this embodiment, the amplifiers A1(1) to A1(M) and A2(1) to A2(N) are implemented by variable gain amplifiers or buffers, respectively.

In this embodiment, the resonator 420 includes a resonant buffer 421, a resonant inductor LR, and a resonant capacitor CR. An input terminal of the resonant buffer 421 receives an input signal SIN. The output terminal of the resonant buffer 421 outputs a high-frequency resonance signal SR. The resonant inductor LR is coupled between the output terminal of the resonant buffer 421 and the reference bias voltage VB. The resonant capacitor CR is coupled between the output terminal of the resonant buffer 421 and the reference bias voltage VB. In some embodiments, the resonant capacitor CR may be a variable capacitor.

Taking this embodiment as an example, the resonant buffer 421 receives the input signal SIN via the high-pass filter 360. Therefore, the resonant buffer 421 receives the high frequency component of the input signal SIN. The resonant inductor LR may provide a resonant inductance value. The parasitic resistance of the resonant inductor LR may provide a resonant resistance value. The resonant capacitor CR may provide a resonant capacitance value. The resonant inductor LR and the resonant capacitor CR may form a resonance tank to perform a high-frequency resonance operation on the high frequency component of the input signal SIN.

In some embodiments, the high-pass filter 360 may be omitted.

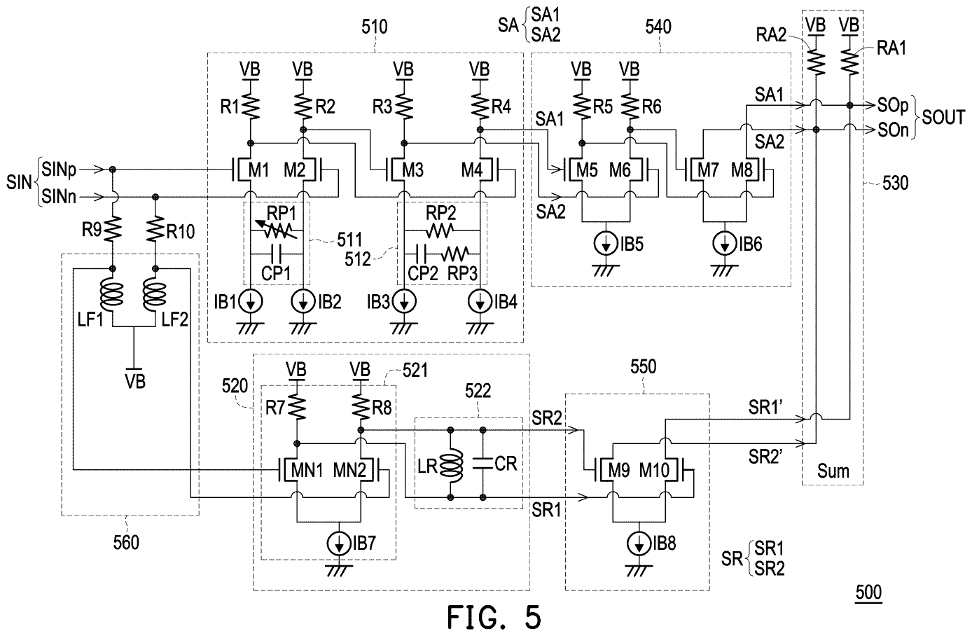

Referring to FIG. 5, FIG. 5 is a schematic diagram of a signal transmission circuit according to an embodiment of the disclosure. In this embodiment, the signal transmission circuit 500 includes an equalizer 510, a resonator 520, an adder 530, a delay circuit 540, a delay buffer 550, and a high-pass filter 560. The equalizer 510 includes equalizing transistors M1 to M4, current sources IB1 to IB4, resistors R1 to R4, and parameter circuits 511 and 512. A first terminal of the equalizing transistor M1 is coupled to a reference bias voltage VB. The first terminal of the equalizing transistor M1 is coupled to the reference bias voltage VB via a resistor R1. A control terminal of the equalizing transistor M1 receives the first differential input signal SINp of the input signal SIN. A first terminal of the equalizing transistor M2 is coupled to a reference bias voltage VB. A first terminal of the equalizing transistor M2 is coupled to the reference bias voltage VB via the resistor R2. A control terminal of the equalizing transistor M2 receives the second differential input signal SINn of the input signal SIN. The current source IB1 is coupled between the second terminal of the equalizing transistor M1 and a reference low voltage (e.g., the ground). The current source IB2 is coupled between the second terminal of the equalizing transistor M2 and a reference low voltage (e.g., the ground). The current sources IB1 and IB2 are configured to provide bias current for the equalizer 510.

In this embodiment, the parameter circuit 511 is coupled between the second terminal of the equalizing transistor M1 and the second terminal of the equalizing transistor M2. The parameter circuit 511 may be configured to adjust at least one of the gain and bandwidth of the equalizer 510. The parameter circuit 511 includes a resistor RP1 and a capacitor CP1. The resistor RP1 is coupled between the second terminal of the equalizing transistor M1 and the second terminal of the equalizing transistor M2. The capacitor CP1 is coupled between the second terminal of the equalizing transistor M1 and the second terminal of the equalizing transistor M2. The resistor RP1 may be a variable resistor. The resistor RP1 may provide a variable resistance value. The change of the variable resistor value may be used to adjust the gain of the equalizer 510. For example, the higher the variable resistance value, the lower the gain of the equalizer 510. The lower the variable resistance value, the higher the gain of the equalizer 510.

In some embodiments, the capacitor CP1 may be a variable capacitor. The capacitor CP1 may provide a variable capacitance value. The change of the variable capacitance value may be used to adjust the bandwidth of the equalizer 510. For example, the higher the variable capacitance value, the smaller the bandwidth of the equalizer 510. The lower the variable capacitance value, the larger the bandwidth of the equalizer 510.

In this embodiment, the first terminal of the equalizing transistor M3 is coupled to the reference bias voltage VB. A first terminal of the equalizing transistor M3 is coupled to the reference bias voltage VB via a resistor R3. The control terminal of the equalizing transistor M3 is coupled to the first terminal of the equalizing transistor M2. A first terminal of the equalizing transistor M4 is coupled to the reference bias voltage VB. A first terminal of the equalizing transistor M4 is coupled to the reference bias voltage VB via a resistor R4. The control terminal of the equalizing transistor M4 is coupled to the first terminal of the equalizing transistor M1. The current source IB3 is coupled between the second terminal of the equalizing transistor M3 and a reference low voltage (e.g., the ground). The current source IB4 is coupled between the second terminal of the equalizing transistor M4 and a reference low voltage (e.g., the ground). The current sources IB3 and IB4 are configured to provide bias current for the equalizer 510.

In this embodiment, the parameter circuit 512 is coupled between the second terminal of the equalizing transistor M3 and the second terminal of the equalizing transistor M4. The first terminal of the equalizing transistor M3 outputs a first differential gain signal SA1 of the gain signal SA. The first terminal of the equalizing transistor M4 outputs a second differential gain signal SA2 of the gain signal SA.

In this embodiment, the parameter circuit 512 includes resistors RP2 and RP3 and a capacitor CP2. The resistor RP2 is coupled between the second terminal of the equalizing transistor M3 and the second terminal of the equalizing transistor M4. The resistor RP2 and the capacitor CP2 are connected in series between the second terminal of the equalizing transistor M3 and the second terminal of the equalizing transistor M4. The resistors RP2 and RP3 each have a fixed resistance value. The capacitor CP2 has a fixed capacitance value.

In some embodiments, the parameter circuit 512 may also be configured to adjust at least one of the gain and bandwidth of the equalizer 510. For example, at least one of the resistors RP2 and RP3 may be a variable resistor. For example, the capacitor CP2 may be a variable capacitor.

In some embodiments, the circuit implementation of the parameter circuit 512 may be similar to the circuit implementation of the parameter circuit 511.

In this embodiment, the equalizing transistors M1 and M2, the current sources IB1 and IB2, the resistors R1 and R2, and the parameter circuit 511 may be a first-stage circuit of the equalizer 510. The equalizing transistors M3 and M4, the current sources IB3 and IB4, the resistors R3 and R4, and the parameter circuit 512 may be a second-stage circuit of the equalizer 510.

In some embodiments, the second-stage circuit of the equalizer 510 may be omitted. Therefore, the first terminal of the equalizing transistor M1 outputs the first differential gain signal SA1 of the gain signal SA. The first terminal of the equalizing transistor M2 outputs a second differential gain signal SA2 of the gain signal SA.

In this embodiment, the delay circuit 540 includes transistors M5 to M8, current sources IB5 and IB6, and resistors R5 and R6. A first terminal of the transistor M5 is coupled to the reference bias voltage VB. A first terminal of the transistor M5 is coupled to the reference bias voltage VB via a resistor R5. The control terminal of the transistor M5 receives the first differential gain signal SA1. A first terminal of the transistor M6 is coupled to the reference bias voltage VB. A first terminal of the transistor M6 is coupled to the reference bias voltage VB via a resistor R6. The control terminal of the transistor M6 receives the second differential gain signal SA2. The current source IB5 is coupled to the second terminals of the transistors M5 and M6 and the reference low voltage. A first terminal of the transistor M7 is coupled to the adder 530. The control terminal of the transistor M7 is coupled to the first terminal of the transistor M6. A first terminal of the transistor M8 is coupled to the adder 530. The control terminal of the transistor M8 is coupled to the first terminal of the transistor M5. The current source IB6 is coupled to the second terminals of the transistors M7 and M8 and the reference low voltage. The current sources IB5 and IB6 are configured to provide bias current for the delay circuit 540.

In this embodiment, the first terminal of the transistor M8 outputs the delayed first differential gain signal SA1′. The first terminal of the transistor M7 outputs the delayed second differential gain signal SA2′.

In this embodiment, the resistors R5 and R6, the transistors M5 and M6, and the current source IB5 may be a first-stage circuit of the delay circuit 540. The transistors M7 and M8 and the current source IB6 may be a second-stage circuit of the delay circuit 540.

In this embodiment, the high-pass filter 560 includes inductors LF1 and LF2. A first terminal of the inductor LF1 is coupled to the reference bias voltage VB. A second terminal of the inductor LF1 is coupled to the resonator 520. The second terminal of the inductor LF1 receives the first differential input signal SINp of the input signal SIN via the resistor R9. A first terminal of the inductor LF2 is coupled to the reference bias voltage VB. A second terminal of the inductor LF2 is coupled to the resonator 520. The second terminal of the inductor LF2 receives the second differential input signal SINn of the input signal SIN via the resistor R10. The high-pass filter 560 filters out low frequency component of the first differential input signal SINp of the input signal SIN, and filters out low frequency component of the second differential input signal SINn of the input signal SIN.

In this embodiment, the resonator 520 includes a resonant buffer 521 and a resonant circuit 522. The resonant buffer 521 includes resistors R7 and R8, resonant transistors MN1 and MN2, and a resonant current source IB7. A first terminal of the resonant transistor MN1 is coupled to the reference bias voltage VB. A first terminal of the resonant transistor MN1 is coupled to the reference bias voltage VB via the resistor R7. The control terminal of the resonant transistor MN1 receives the first differential input signal SINp. It should be noted that the high-pass filter 560 filters out the low frequency component of the first differential input signal SINp of the input signal SIN. Therefore, the control terminal of the resonant transistor MN1 receives the high frequency component of the first differential input signal SINp. A first terminal of the resonant transistor MN2 is coupled to the reference bias voltage VB. A first terminal of the resonant transistor MN2 is coupled to the reference bias voltage VB via the resistor R8. The control terminal of the resonant transistor MN2 receives the second differential input signal SINn. It should be noted that the high-pass filter 560 filters out the low frequency component of the second differential input signal SINn of the input signal SIN. Therefore, the control terminal of the resonant transistor MN2 receives the high frequency component of the second differential input signal SINn.

The resonant current source IB7 is coupled to the resonant transistors MN1 and MN2 and the reference low voltage. The resonant current source IB7 is configured to provide a bias current for the resonator 520.

The resonant circuit 522 includes a resonant capacitor CR and a resonant inductor LR. The resonant capacitor CR is coupled between the first terminal of the resonant transistor MN1 and the first terminal of the resonant transistor MN2. The resonant inductor LR is coupled between the first terminal of the resonant transistor MN1 and the first terminal of the resonant transistor MN2. The resonant inductor LR and the resonant capacitor CR may form a resonance tank to perform high-frequency resonance operation on the high frequency component of the first differential input signal SINp and the high frequency component of the second differential input signal SINn to generate the first differential resonance signal SR1 and the second differential resonance signal SR2.

In this embodiment, the delay buffer 550 includes transistors M9 and M10 and a current source IB8. A first terminal of the transistor M9 is coupled to the adder 530. The control terminal of the transistor M9 is coupled to the first terminal of the resonant transistor MN2 to receive the second differential resonance signal SR2. A first terminal of the transistor M10 is coupled to the adder 530. The control terminal of the transistor M10 is coupled to the first terminal of the transistor M7 to receive the first differential resonance signal SR1. The current source IB8 is coupled to the second terminals of the transistors M9 and M10 and the reference low voltage.

In this embodiment, the first terminal of the transistor M10 outputs the delayed first differential resonance signal SR1′. The first terminal of the transistor M9 outputs the delayed second differential resonance signal SR2′. The current source IB8 is configured to provide a bias current for the delay buffer 550.

In this embodiment, the adder 530 includes resistors RA1 and RA2. A first terminal of the resistor RA1 is coupled to the reference bias voltage VB. The second terminal of the resistor RA1 receives the delayed first differential resonance signal SR1′ and the delayed first differential gain signal SA1′. Therefore, the adder 530 may sum the delayed first differential resonance signal SR1′ and the delayed first differential gain signal SA1′ to generate the first differential output signal SOp of the output signal SOUT.

A first terminal of the resistor RA2 is coupled to the reference bias voltage VB. The second terminal of the resistor RA2 receives the delayed second differential resonance signal SR2′ and the delayed second differential gain signal SA2′. Therefore, the adder 530 may sum the delayed second differential resonance signal SR2′ and the delayed second differential gain signal SA2′ to generate the second differential output signal SOn of the output signal SOUT.

In some embodiments, the resistors R1 to R10 may be omitted. The resistors R1 to R10 may be replaced by parasitic resistance of the line itself.

In this embodiment, the equalizing transistors M1 to M4, the transistors M5 to M10, and the resonant transistors MN1 and MN2 are respectively implemented by N-type transistors. The disclosure is not limited to the type of N-type transistor.

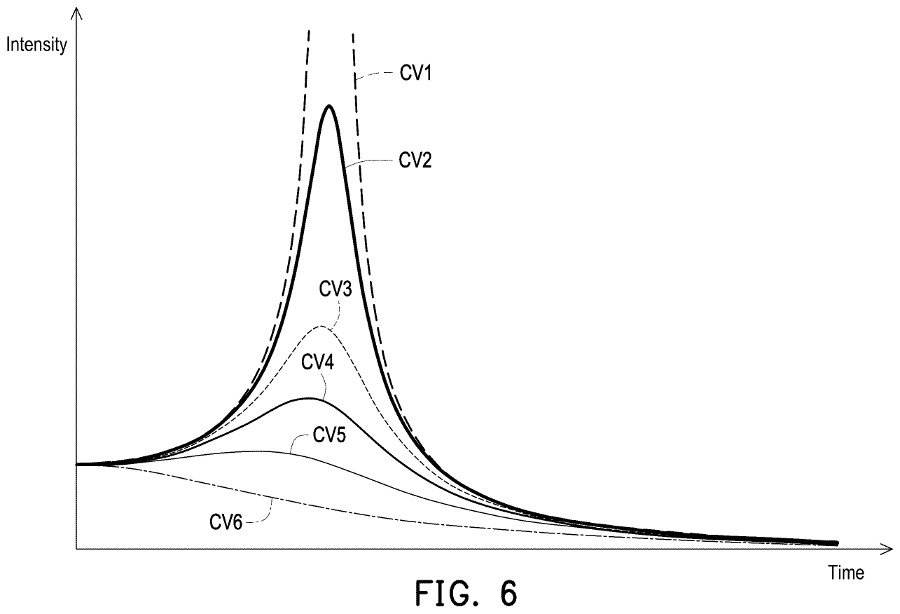

Referring to FIG. 5 and FIG. 6, FIG. 6 is a diagram of a damping response of a resonator according to an embodiment of the disclosure. In this embodiment, FIG. 6 shows curves CV1 to CV6. The horizontal axis represents time. The vertical axis represents the intensity of the signal (e.g., the first differential resonance signal SR1 and the second differential resonance signal SR2). The curves CV1 to CV6 respectively represent different damping responses provided by the resonant circuit 522 of the resonator 520. The resonant capacitor CR may provide a resonant capacitance value. The resonant inductor LR provides a resonant inductance value and a resonant resistance value. The resonant capacitance value, the resonant inductance value, and the resonant resistance value may determine the damping coefficient. Curve CV1 is the damping response corresponding to a damping coefficient equal to “0”. Curve CV2 is the damping response corresponding to a damping coefficient equal to “0.1”. Curve CV3 is the damping response corresponding to a damping coefficient equal to “0.2”. Curve CV4 is the damping response corresponding to a damping coefficient equal to “0.3”. Curve CV5 is the damping response corresponding to a damping coefficient equal to “0.5”. Curve CV6 is the damping response corresponding to a damping coefficient equal to “1”. As shown in FIG. 6, curves CV1 to CV4 have a resonant response. Therefore, the damping coefficient may be designed to be less than 0.5, so that the resonant circuit 522 has a resonance functionality.

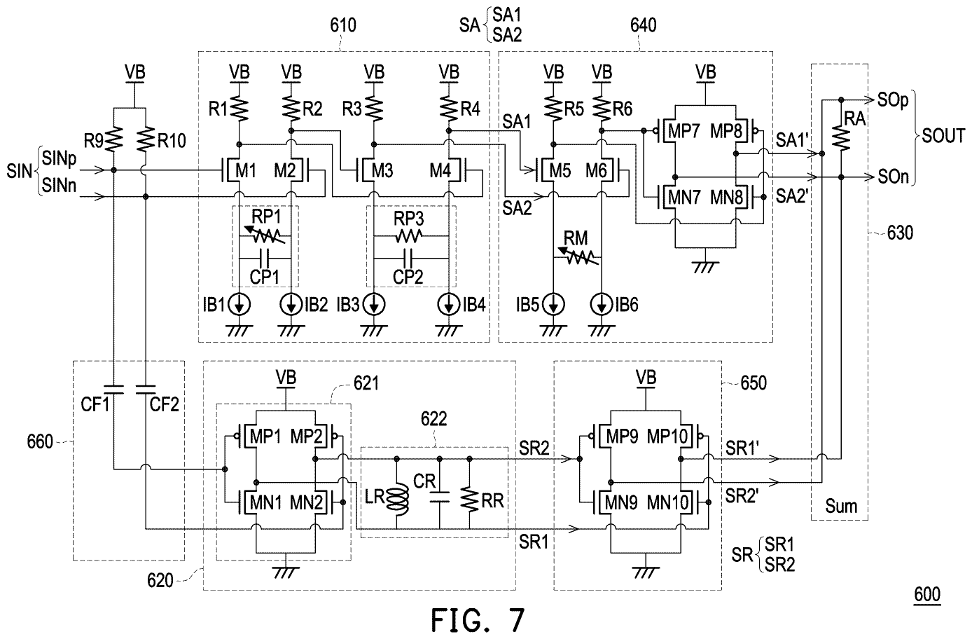

Referring to FIG. 7, FIG. 7 is a schematic diagram of a signal transmission circuit according to an embodiment of the disclosure. In this embodiment, the signal transmission circuit 600 includes an equalizer 610, a resonator 620, an adder 630, a delay circuit 640, a delay buffer 650, and a high-pass filter 660. The equalizer 610 includes equalizing transistors M1 to M4, current sources IB1 to IB4, resistors R1 to R4, and parameter circuits 611 and 612. The implementation of the equalizing transistors M1 and M2, current sources IB1 and IB2, resistors R1 and R2 and the parameter circuit 611 is similar to the implementation of the equalizing transistors M1 and M2, current sources IB1 and IB2, resistors R1 and R2 and the parameter circuit 611 shown in FIG. 5, so it is not repeated herein.

In this embodiment, the first terminal of the equalizing transistor M3 is coupled to the reference bias voltage VB. A first terminal of the equalizing transistor M3 is coupled to the reference bias voltage VB via a resistor R3. The control terminal of the equalizing transistor M3 is coupled to the first terminal of the equalizing transistor M2. A first terminal of the equalizing transistor M4 is coupled to the reference bias voltage VB. A first terminal of the equalizing transistor M4 is coupled to the reference bias voltage VB via a resistor R4. The control terminal of the equalizing transistor M4 is coupled to the first terminal of the equalizing transistor M1. The current source IB3 is coupled between the second terminal of the equalizing transistor M3 and a reference low voltage (e.g., the ground). The current source IB4 is coupled between the second terminal of the equalizing transistor M4 and a reference low voltage (e.g., the ground). The parameter circuit 612 is coupled between the second terminal of the equalizing transistor M3 and the second terminal of the equalizing transistor M4.

In this embodiment, the first terminal of the equalizing transistor M3 outputs a first differential gain signal SA1 of the gain signal SA. The first terminal of the equalizing transistor M4 outputs a second differential gain signal SA2 of the gain signal SA.

In this embodiment, the parameter circuit 612 includes a resistor RP2 and a capacitor CP2. The resistor RP2 is coupled between the second terminal of the equalizing transistor M3 and the second terminal of the equalizing transistor M4. The resistor RP2 and the capacitor CP2 are connected in series between the second terminal of the equalizing transistor M3 and the second terminal of the equalizing transistor M4. The resistor RP2 has a fixed resistance value. The capacitor CP2 has a fixed capacitance value.

In some embodiments, the resistor RP2 may be a variable resistor. The capacitor CP2 may be a variable capacitor.

In this embodiment, the equalizing transistors M1 and M2, the current sources IB1 and IB2, the resistors R1 and R2, and the parameter circuit 611 may be a first-stage circuit of the equalizer 610. The equalizing transistors M3 and M4, the current sources IB3 and IB4, the resistors R3 and R4, and the parameter circuit 612 may be a second-stage circuit of the equalizer 610.

In some embodiments, the second-stage circuit of the equalizer 610 may be omitted. Therefore, the first terminal of the equalizing transistor M1 outputs the first differential gain signal SA1 of the gain signal SA. The first terminal of the equalizing transistor M2 outputs a second differential gain signal SA2 of the gain signal SA.

In this embodiment, the delay circuit 540 includes transistors M5, M6, MN7, MN8, MP7 and MP8, current sources IB5 and IB6, and resistors R5, R6 and RM. A first terminal of the transistor M5 is coupled to the reference bias voltage VB. A first terminal of the transistor M5 is coupled to the reference bias voltage VB via a resistor R5. The control terminal of the transistor M5 receives the first differential gain signal SA1. A first terminal of the transistor M6 is coupled to the reference bias voltage VB. A first terminal of the transistor M6 is coupled to the reference bias voltage VB via a resistor R6. The control terminal of the transistor M6 receives the second differential gain signal SA2. The current source IB5 is coupled to the second terminal of the transistor M5 and the reference low voltage. The current source IB6 is coupled to the second terminal of the transistor M6 and the reference low voltage. The resistor RM is coupled between the second terminal of the transistor M5 and the second terminal of the transistor M6.

A first terminal of the transistor MP7 is coupled to the reference bias voltage VB. A second terminal of the transistor MP7 is coupled to the adder 530. The control terminal of the transistor MP7 is coupled to the first terminal of the transistor M6. A first terminal of the transistor MP8 is coupled to the reference bias voltage VB. The control terminal of the transistor MP8 is coupled to the first terminal of the transistor M5. A second terminal of the transistor MP8 is coupled to the adder 530. A first terminal of the transistor MN7 is coupled to a second terminal of the transistor MP7. A second terminal of the transistor MN7 is coupled to the reference low voltage. The control terminal of the transistor MN7 is coupled to the first terminal of the transistor M6. A first terminal of the transistor MN8 is coupled to a second terminal of the transistor MP8. A second terminal of the transistor MN8 is coupled to the reference low voltage. The control terminal of the transistor MN8 is coupled to the first terminal of the transistor M5.

In this embodiment, the first terminal of the transistor MN8 outputs the delayed first differential gain signal SA1′. The first terminal of the transistor MN7 outputs the delayed second differential gain signal SA2′.

In this embodiment, the transistors M5 and M6, the current sources IB5 and IB6, and the resistor RM may be a first-stage circuit of the delay circuit 640. The transistors MN7, MN8, MP7, and MP8 may be a second-stage circuit of the delay circuit 640.

In this embodiment, the high-pass filter 660 includes capacitors CF1 and CF2. The first terminal of the capacitor CF1 receives the first differential input signal SINp of the input signal SIN. A first terminal of the capacitor CF1 is coupled to the reference bias voltage VB via the resistor R9. A second terminal of the capacitor CF1 is coupled to the resonator 620. A first terminal of the capacitor CF2 receives the second differential input signal SINn of the input signal SIN. A first terminal of the capacitor CF2 is coupled to the reference bias voltage VB via the resistor R10. A second terminal of the capacitor CF2 is coupled to the resonator 620. The high-pass filter 660 filters out low frequency component of the first differential input signal SINp of the input signal SIN, and filters out low frequency component of the second differential input signal SINn of the input signal SIN.

In this embodiment, the resonator 620 includes a resonant buffer 621 and a resonant circuit 622. The resonant buffer 621 includes resonant transistors MN1, MN2, MP1, and MP2. A first terminal of the transistor MP1 is coupled to the reference bias voltage VB. A control terminal of the transistor MP1 receives the first differential input signal SINp of the input signal SIN. A first terminal of the resonant transistor MN1 is coupled to a second terminal of the transistor MP1. A second terminal of the resonant transistor MN1 is coupled to the reference low voltage. A control terminal of the transistor MN1 receives the first differential input signal SINp of the input signal SIN. It should be noted that the high-pass filter 660 filters out the low frequency component of the first differential input signal SINp of the input signal SIN. Therefore, the control terminals of the resonant transistors MP1 and MN1 receive the high frequency component of the first differential input signal SINp. A first terminal of the transistor MP2 is coupled to the reference bias voltage VB. A control terminal of the transistor MP2 receives the second differential input signal SINn of the input signal SIN. A first terminal of the resonant transistor MN2 is coupled to a second terminal of the transistor MP2. A second terminal of the resonant transistor MN2 is coupled to the reference low voltage. A control terminal of the transistor MN2 receives the second differential input signal SINn of the input signal SIN. It should be noted that the high-pass filter 660 filters out the low frequency component of the second differential input signal SINn of the input signal SIN. Therefore, the control terminals of the resonant transistors MP2 and MN2 receive the high frequency component of the second differential input signal SINn.

The resonant circuit 622 includes a resonant resistor RR, a resonant capacitor CR, and a resonant inductor LR. The resonant capacitor CR is coupled between the first terminal of the resonant transistor MN1 and the first terminal of the resonant transistor MN2. The resonant resistor RR is coupled between the first terminal of the resonant transistor MN1 and the first terminal of the resonant transistor MN2. The resonant inductor LR is coupled between the first terminal of the resonant transistor MN1 and the first terminal of the resonant transistor MN2. The resonant inductor LR and the resonant capacitor CR may form a resonance tank to perform high-frequency resonance operation on the high frequency component of the first differential input signal SINp and the high frequency component of the second differential input signal SINn to generate the first differential resonance signal SR1 and the second differential resonance signal SR2.

In some embodiments, the resonant capacitor CR may be a variable capacitor. In some embodiments, the resonant resistor RR may be a variable resistor.

In some embodiments, the resonant resistor RR may be omitted. The resonant resistor RR may be replaced by the parasitic resistance of the resonant inductor LR.

In this embodiment, the delay buffer 650 includes transistors MN9, MN10, MP9, and MP10. A first terminal of the transistor MP9 is coupled to the reference bias voltage VB. The control terminal of the transistor MP9 is coupled to the first terminal of the resonant transistor MN2 to receive the second differential resonance signal SR2. A first terminal of the transistor MN9 is coupled to a second terminal of the transistor MP9. A second terminal of the transistor MN9 is coupled to the reference low voltage. The control terminal of the transistor MN9 is coupled to the first terminal of the resonant transistor MN2 to receive the second differential resonance signal SR2.

A first terminal of the transistor MP10 is coupled to the reference bias voltage VB. The control terminal of the transistor MP10 is coupled to the first terminal of the resonant transistor MN1 to receive the first differential resonance signal SR1. A first terminal of the transistor MN10 is coupled to a second terminal of the transistor MP10. A second terminal of the transistor MN10 is coupled to the reference low voltage. The control terminal of the transistor MN10 is coupled to the first terminal of the resonant transistor MN1 to receive the first differential resonance signal SR1.

In this embodiment, the first terminal of the transistor MN10 outputs the delayed first differential resonance signal SR1′. The first terminal of the transistor MN9 outputs the delayed second differential resonance signal SR2′.

In this embodiment, the adder 630 includes a resistor RA. The first terminal of the resistor RA receives the delayed first differential resonance signal SR1′ and the delayed first differential gain signal SA1′. Therefore, the first terminal of the resistor RA may sum the delayed first differential resonance signal SR1′ and the delayed first differential gain signal SA1′ to generate the first differential output signal SOp of the output signal SOUT. The second terminal of the resistor RA receives the delayed second differential resonance signal SR2′ and the delayed second differential gain signal SA2′. Therefore, the second terminal of the resistor RA may sum the delayed second differential resonance signal SR2′ and the delayed second differential gain signal SA2′ to generate the second differential output signal SOn of the output signal SOUT.

In this embodiment, the equalizing transistors M1 to M4, the transistors M5, M6, MN7 to MN10, and the resonant transistors MN1 and MN2 are respectively implemented by N-type transistors. The disclosure is not limited to the type of N-type transistor. The transistors MP7 to MP10 and the resonant transistors MP1 and MP2 are respectively implemented by P-type transistors. The disclosure is not limited to the type of P-type transistor.

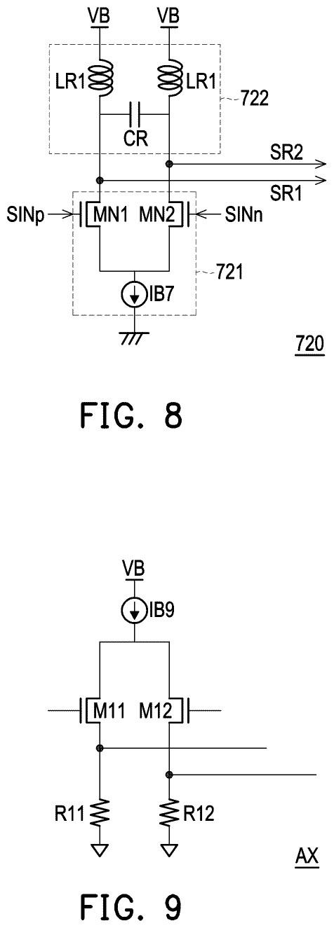

Referring to FIG. 8, FIG. 8 is a schematic diagram of a resonator according to an embodiment of the disclosure. In this embodiment, the resonator 720 includes a resonant buffer 721 and a resonant circuit 722. The resonant circuit 722 includes a resonant capacitor CR and resonant inductors LR1 and LR2. The resonant inductor LR1 is coupled between the reference bias voltage VB and the first terminal of the resonant capacitor CR. The resonant inductor LR2 is coupled between the reference bias voltage VB and the second terminal of the resonant capacitor CR. In this embodiment, the resonant inductors LR1 and LR2 each have a parasitic resistance to generate a resonant resistance value. In some embodiments, the resonant capacitor CR may be a variable capacitor.

In this embodiment, the resonant buffer 721 includes resonant transistors MN1 and MN2 and a current source IB7. A first terminal of the resonant transistor MN1 is coupled to a first terminal of the resonant capacitor CR. The control terminal of the resonant transistor MN1 receives the first differential input signal SINp. A first terminal of the resonant transistor MN2 is coupled to a second terminal of the resonant capacitor CR. The control terminal of the resonant transistor MN2 receives the second differential input signal SINn. The resonant current source IB7 is coupled to the second terminal of the resonant transistor MN1 and the second terminal of the resonant transistor MN2. In this embodiment, the first terminal of the resonant transistor MN1 is configured to provide the first differential resonance signal SR1. The first terminal of the resonant transistor MN2 is configured to provide the second differential resonance signal SR2.

In this embodiment, the resonant transistors MN1 and MN2 are respectively implemented by N-type transistors.

Referring to FIG. 5, FIG. 7, and FIG. 8, the resonator 520 of FIG. 5 may be replaced by one of the resonator 620 of FIG. 7 and the resonator 720 of FIG. 8. The resonator 620 of FIG. 7 may be replaced by one of the resonator 520 of FIG. 5 and the resonator 720 of FIG. 8.

Referring to FIG. 4 and FIG. 9, FIG. 9 is a schematic diagram of an amplifier according to an embodiment of the disclosure. In this embodiment, the amplifiers A1(1) to A1(M) and A2(1) to A2(N) may be respectively implemented by an amplifier AX. The amplifier AX includes a current source IB9, transistors M11 and M12, and resistors R11 and R12. A first terminal of the current source IB9 is coupled to the reference bias voltage VB. A first terminal of the transistor M11 is coupled to a second terminal of the current source IB9. A first terminal of the transistor M12 is coupled to a second terminal of the current source IB9. The resistor R11 is coupled between the second terminal of the transistor M11 and the reference low voltage. The resistor R12 is coupled between the second terminal of the transistor M12 and the reference low voltage. In this embodiment, the control terminals of the transistors M11 and M12 receive an input signal SIN in a differential signal format or a differential signal of an amplifier of the previous stage. The second terminals of the transistors M11 and M12 output a differential signal in a differential signal format to an amplifier of a subsequent stage or the adder 230.

In some embodiments, amplifiers A1(1) to A1(M) and A2(1) to A2(N) may be respectively implemented by one of a first-stage circuit of the delay circuit 540 as shown in FIG. 5 (i.e., a circuit combination of resistors R5 and R6, transistors M5 and M6, and the current source IB5), a second-stage circuit of the delay circuit 540 as shown in FIG. 5 (i.e., a circuit combination of transistors M7 and M8 and the current source IB6), a second-stage circuit of the delay circuit 640 as shown in FIG. 6 (i.e., a circuit combination of transistors MN7, MN8, MP7 and MP8), and the amplifier AX of FIG. 9.

To sum up, the resonator performs a high-frequency resonance operation on the input signal to generate a high-frequency resonance signal. The adder compensates the gain signal SA with the high-frequency resonance signal to generate an output signal. In this way, the high frequency portion of the output signal may be compensated by the high-frequency resonance signal.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A signal transmission circuit for high frequency transmission, comprising:
an equalizer, configured to receive an input signal and gain the input signal to generate a gain signal;
a resonator, configured to receive the input signal and perform a high-frequency resonance operation on the input signal to generate a high-frequency resonance signal; and
an adder, coupled to the equalizer and the resonator, configured to receive the gain signal and the high-frequency resonance signal and sum the gain signal and the high-frequency resonance signal to generate an output signal.

2. The signal transmission circuit according to claim 1, wherein the equalizer comprises:
a first equalizing transistor, wherein a first terminal of the first equalizing transistor is coupled to a reference bias voltage, a control terminal of the first equalizing transistor receives a first differential input signal of the input signal;
a second equalizing transistor, wherein a first terminal of the second equalizing transistor is coupled to the reference bias voltage, a control terminal of the second equalizing transistor receives a second differential input signal of the input signal;
a first current source, coupled between a second terminal of the first equalizing transistor and a reference low voltage;
a second current source, coupled between a second terminal of the second equalizing transistor and the reference low voltage; and
a first parameter circuit, coupled between the second terminal of the first equalizing transistor and the second terminal of the second equalizing transistor.

3. The signal transmission circuit according to claim 2, wherein the first parameter circuit comprises:
a first variable resistor, coupled between the second terminal of the first equalizing transistor and the second terminal of the second equalizing transistor and configured to provide a first variable resistance value.

4. The signal transmission circuit according to claim 2, wherein the first parameter circuit comprises:
a first variable capacitor, coupled between the second terminal of the first equalizing transistor and the second terminal of the second equalizing transistor and configured to provide a second variable capacitance value.

5. The signal transmission circuit according to claim 2, wherein the equalizer further comprises:
a third equalizing transistor, wherein a first terminal of the third equalizing transistor is coupled to the reference bias voltage, and a control terminal of the third equalizing transistor is coupled to the first terminal of the second equalizing transistor;
a fourth equalizing transistor, wherein a first terminal of the fourth equalizing transistor is coupled to the reference bias voltage, and a control terminal of the fourth equalizing transistor is coupled to the first terminal of the first equalizing transistor;
a third current source, coupled between a second terminal of the third equalizing transistor and the reference low voltage;
a fourth current source, coupled between a second terminal of the fourth equalizing transistor and the reference low voltage; and
a second parameter circuit, coupled between the second terminal of the third equalizing transistor and the second terminal of the fourth equalizing transistor,
wherein the first terminal of the fourth equalizing transistor outputs a first differential gain signal of the gain signal, and
wherein the first terminal of the third equalizing transistor outputs a second differential gain signal of the gain signal.

6. The signal transmission circuit according to claim 5, wherein the second parameter circuit comprises:
a second variable resistor, coupled between the second terminal of the third equalizing transistor and the second terminal of the fourth equalizing transistor and configured to provide a second variable resistance value.

7. The signal transmission circuit according to claim 5, wherein the second parameter circuit comprises:
a second variable capacitor, coupled between the second terminal of the third equalizing transistor and the second terminal of the fourth equalizing transistor and configured to provide a second variable capacitance value.

8. The signal transmission circuit according to claim 1, further comprising:
a delay circuit, coupled between the equalizer and the adder and configured to delay timing of the gain signal.

9. The signal transmission circuit according to claim 8, further comprising:
a delay buffer, coupled between the resonator and the adder and configured to delay timing of the high-frequency resonance signal.

10. The signal transmission circuit according to claim 9, wherein:
the equalizer and the delay circuit comprise a plurality of first amplifiers,
the delay buffer comprises a plurality of second amplifiers, and
a number of the first amplifiers connected in series is greater than a number of the second amplifiers connected in series.

11. The signal transmission circuit according to claim 1, wherein the resonator comprises:
a resonant buffer, wherein an input terminal of the resonant buffer receives the input signal, wherein an output terminal of the resonant buffer outputs the high-frequency resonance signal;
a resonant inductor, coupled between the output terminal of the resonant buffer and a reference bias voltage; and
a resonant capacitor, coupled between the output terminal of the resonant buffer and the reference bias voltage.

12. The signal transmission circuit according to claim 1, further comprising:
a high-pass filter, coupled to the resonator, configured to receive the input signal and filter out a low frequency component of the input signal, so that the resonator performs the high-frequency resonance operation on a high frequency component of the input signal to generate the high-frequency resonance signal.

13. The signal transmission circuit according to claim 12, wherein the high-pass filter filters out a low frequency component of a first differential input signal of the input signal, and filters out a low frequency component of a second differential input signal of the input signal.

14. The signal transmission circuit according to claim 13, wherein the resonator comprises:
a resonant buffer, comprising:
a first resonant transistor, wherein a first terminal of the first resonant transistor is coupled to a reference bias voltage, and a control terminal of the first resonant transistor receives the first differential input signal;
a second resonant transistor, wherein a first terminal of the second resonant transistor is coupled to the reference bias voltage, and a control terminal of the second resonant transistor receives the second differential input signal; and
a resonant current source, coupled to a second terminal of the first resonant transistor, a second terminal of the second resonant transistor, and a reference low voltage; and
a resonant circuit, comprising:
a resonant capacitor, coupled between the first terminal of the first resonant transistor and the first terminal of the second resonant transistor; and
a resonant inductor, coupled between the first terminal of the first resonant transistor and the first terminal of the second resonant transistor.

15. The signal transmission circuit according to claim 14, further comprising:
a delay buffer, coupled to the second terminal of the first resonant transistor and the second terminal of the second resonant transistor, configured to delay timing of a first resonance signal of the high-frequency resonance signal and timing of a second resonance signal of the high-frequency resonance signal, and providing the first resonance signal and the second resonance signal to the adder.

16. The signal transmission circuit according to claim 13, wherein the resonator comprises:
a resonant buffer, comprising:
a first P-type resonant transistor, wherein a first terminal of the first P-type resonant transistor is coupled to a reference bias voltage, and a control terminal of the first P-type resonant transistor receives the first differential input signal;
a second P-type resonant transistor, wherein a first terminal of the second P-type resonant transistor is coupled to the reference bias voltage, and a control terminal of the second P-type resonant transistor receives the second differential input signal;
a first N-type resonant transistor, wherein a first terminal of the first N-type resonant transistor is coupled to a second terminal of the first P-type resonant transistor, a second terminal of the first N-type resonant transistor is coupled to a reference low voltage, and a control terminal of the first N-type resonant transistor receives the first differential input signal; and
a second N-type resonant transistor, wherein a first terminal of the second N-type resonant transistor is coupled to a second terminal of the second P-type resonant transistor, a second terminal of the second N-type resonant transistor is coupled to the reference low voltage, and a control terminal of the second N-type resonant transistor receives the second differential input signal; and
a resonant circuit, comprising:
a resonant capacitor, coupled between the first terminal of the first N-type resonant transistor and the first terminal of the second N-type resonant transistor; and
a resonant inductor, coupled between the first terminal of the first N-type resonant transistor and the first terminal of the second N-type resonant transistor.

17. The signal transmission circuit according to claim 13, wherein the resonator comprises:
a resonant circuit comprising:
a resonant capacitor;
a first resonant inductor, coupled between a reference bias voltage and a first terminal of the resonant capacitor; and
a second resonant inductor, coupled between the reference bias voltage and a second terminal of the resonant capacitor; and
a resonant buffer comprising:
a first resonant transistor, wherein a first terminal of the first resonant transistor is coupled to the first terminal of the resonant capacitor, a control terminal of the first resonant transistor receives the first differential input signal;
a second resonant transistor, wherein a first terminal of the second resonant transistor is coupled to the second terminal of the resonant capacitor, a control terminal of the second resonant transistor receives the second differential input signal; and
a resonant current source, coupled to a second terminal of the first resonant transistor and a second terminal of the second resonant transistor.
